(19) United States
(12) Patent Application Publication
(10) Pub. No.: US 2012/0200749 A1
(43) Pub. Date: Aug. 9, 2012

(54) IMAGERS WITH STRUCTURES FOR NEAR FIELD IMAGING

(76) Inventors: Ulrich Boettiger, Garden City, ID (US); Swarnal Borthakur, Boise, ID (US); Jeffrey Mackey, Boise, ID (US); Brian Vaartstra, Nampa, ID (US); Marc Sulfridge, Boise, ID (US)

(21) Appl. No.: 13/188,811

(22) Filed: Jul. 22, 2011

Related U.S. Application Data
(60) Provisional application No. 61/439,246, filed on Feb. 3, 2011.

(51) Int. Cl. H04N 9/04

(52) U.S. Cl. 348/273; 348/E09.002

(57) ABSTRACT

An imaging system may include an image sensor configured to image materials at near field imaging ranges from the image sensor. Near field imaging ranges may be on the scale of 1-10 pixel sizes from the image sensor. The materials being imaged may be fluorescent materials that emit radiation at fluorescent wavelengths when the materials are exposed to radiation at excitation wavelengths. The image sensor may include color filter materials that block radiation at excitation wavelengths while transmitting radiation at fluorescent wavelengths. The image sensor may include light guides that reduce cross-talk between pixels and improve localization of emitted radiation, thereby allowing the image sensor to determine which pixel(s) is (are) located beneath the materials being imaged. The light guides may include may include sloped sidewalls and may include reflective sidewalls, which may improve radiation collection (e.g., efficiency) and localization of emitted radiation.

This application claims the benefit of provisional patent application No. 61/439,246, filed Feb. 3, 2011, which is hereby incorporated by reference herein in its entirety.

### BACKGROUND

This relates generally to integrated circuits, and more particularly, to imagers with structures for near field imaging.

Modern electronic devices such as cellular telephones, cameras, and computers often use digital image sensors. Imagers (i.e., image sensors) may be formed from a two-dimensional array of image sensing pixels. Each pixel receives incident photons (light) and converts the photons into electrical signals.

Modern imagers are not satisfactory for use in imaging objects at near field ranges. At near field ranges, objects are typically located at close distances to an imager (e.g., on the surface of the imager or within a few pixel sizes worth of vertical distance from the imager).

It would therefore be desirable to provide imagers with structures for near field imaging.

### BRIEF DESCRIPTION OF THE DRAWINGS

FIG. 1 is a diagram of an illustrative integrated circuit with image sensor circuitry that may include pixel light guide structures such as pixel light guide structures for near field imaging in accordance with an embodiment of the present invention.

FIG. 2 is a cross-sectional side view of an illustrative imager that may include dual light guide structures in accordance with an embodiment of the present invention.

FIG. 3 is a cross-sectional side view of an illustrative imager that may include single light guide structures in accordance with an embodiment of the present invention.

FIG. 4 is a cross-sectional side view of an illustrative imager that may include dual light guide structures having tapered shapes and having light blocking layers that extend along at least part of the walls of the light guide structures in accordance with an embodiment of the present invention.

FIG. 5 is a cross-sectional side view of an illustrative imager that may include dual light guide structures having block shapes and that may be topped by light blocking layers in accordance with an embodiment of the present invention.

FIG. 6 is a cross-sectional side view of an illustrative imager that may include single light guide structures having tapered shapes and having light blocking layers that extend along the walls of the single light guide structures in accordance with an embodiment of the present invention.

FIG. 7 is a cross-sectional side view of an illustrative imager that may include light guide structures having inwardly-sloped shapes in accordance with an embodiment of the present invention.

FIG. 8 is a cross-sectional side view of an illustrative imager that may include light guide structures having outwardly-sloped (e.g., retrograde) shapes in accordance with an embodiment of the present invention.

FIG. 9 is a top view of an illustrative imager that may include light guide structures showing how the imager may be dividing into two or more portions in accordance with an embodiment of the present invention.

FIG. 10 is a top view of an illustrative group of four pixels that may include light guide structures and that have rectangular shapes in accordance with an embodiment of the present invention.

FIG. 11 is a top view of an illustrative group of four pixels that may include light guide structures and that have irregular pentagonal shapes in accordance with an embodiment of the present invention.

FIG. 12 is a series of cross-sectional side views showing illustrative processes that may be used in forming an imager that may include light guide structures in accordance with an embodiment of the present invention.

FIG. 13 is a flowchart of illustrative steps involved in forming an imager that may include light guide structures in accordance with an embodiment of the present invention.

### DETAILED DESCRIPTION

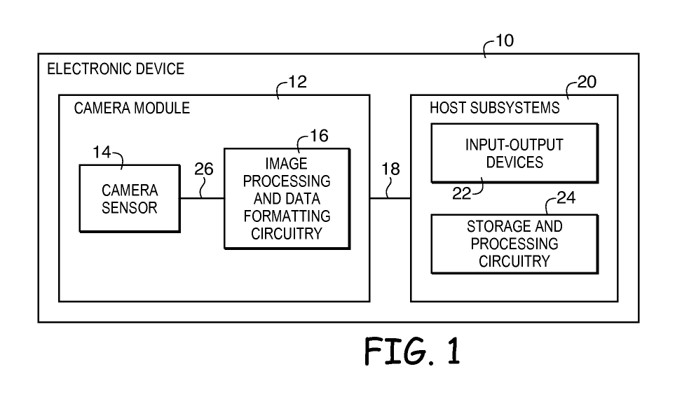

An electronic device with a digital camera module is shown in FIG. 1. Electronic device 10 may be a digital camera, a computer, a cellular telephone, a medical device, or other electronic device. Camera module 12 may include image sensor 14 and one or more lenses. During operation, the lenses focus light onto image sensor 14. Image sensor 14 includes photosensitive elements (i.e., pixels) that convert the light into digital data. Image sensors may have any number of pixels (e.g., hundreds, thousands, millions, or more). A typical image sensor may, for example, have millions of pixels (e.g., megapixels).

Still and video image data from camera sensor 14 may be provided to image processing and data formatting circuitry 16 via path 26. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip or SOC arrangement, camera sensor 14 and image processing and data formatting circuitry 16 are implemented on a common integrated circuit. The use of a single integrated circuit to implement camera sensor 14 and image processing and data formatting circuitry 16 can help to minimize costs.

Camera module 12 (e.g., image processing and data formatting circuitry 16) conveys acquired image data to host subsystem 20 over path 18. Electronic device 10 typically provides a user with numerous high-level functions. In a computer or advanced cellular telephone, for example, a user may be provided with the ability to run user applications. To implement these functions, host subsystem 20 of electronic device 10 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, etc.

Image sensor 14 may, if desired, be designed to image objects within near field imaging regimes. As one example, image sensor 14 may be configured to detect light (e.g., radiation) emanating from sources that are relatively small compared to the size of individual pixels within image sensor 14. Alternatively or in addition, image sensor 14 may be configured to detect light emanating from sources that are relatively near to image sensor 14 (e.g., sources that are on the surface of image sensor 14, that are within a single pixel size distance of image sensor 14, that are within 1-10 pixel size distances of image sensor 14, that are within 5 pixel size distances of image sensor 14, that are within 10 pixel size distances of image sensor 14, that are within 15 pixel size distances of image sensor 14, that are within 20 pixel size distances of image sensor 14, that are within 25 pixel size distances of image sensor 14, that are within 50 pixel size distances of image sensor 14, or that are within another desired distance). As an example, image sensor 14 may be used in an opto-fluidic microscope.

If desired, when camera module 12 is configured to image objects within near field imaging regimes, camera module 12 may function without many of the lenses required by conventional cameras. As an example, while camera sensor 14 may include an array of microlenses (e.g., an array of lenses, each of which is above a respective one of the pixels in an array of pixels and each of which focuses light onto the photosensitive areas of that respective pixel), camera module 12 may not include any lenses of the type sometimes referred to as macro-lenses (e.g., camera module 12 may not include a conventional lens used to refract light from an object being imaged onto an entire array of imaging sensing pixels in a conventional camera sensor).

Objects that may be imaged by image sensor 14 include, but are not limited to, cells, nanoparticles, proteins, protein structures, molecules, and any other micro-entity such as minerals, crystals, etc. that either fluoresces naturally or can be (uniquely) tagged with a fluorescent marker.

With some arrangements, image sensor 14 may be configured to accurately localize objects imaged within such near field regimes (e.g. image sensor 14 may determine where such objects are located over image sensor 14, the size of such objects, the velocity of such objects, etc.). Optical cross-talk (e.g., leakage of light between pixels of image sensor 14), when imaging near-field objects, may also be reduced to enhance and/or optimize the imaging performance of image sensor 14.

With some suitable arrangements, near field objects may emit (rather than merely reflect) electromagnetic radiation that can be detected by image sensor 14. For example, near field objects may be fluorescent, or may be tagged with fluorescent particles (sometimes referred to herein as fluorescent markers). With such arrangements, excitation radiation from a suitable source may be used to stimulate the fluorescence of objects imaged by imager sensor 14 (e.g., objects within the near field regime of image sensor 14). In some arrangements, excitation light may be provided using a pulsed light sourced (e.g., flashed excitation). If desired, image sensor 14 may include filter structures that filter excitation radiation wavelengths while passing fluorescent radiation wavelengths.

Image sensor 14 may be capable of determining how much of a particular substance is being imaged. For example, when image sensor 14 detects high levels of fluorescent light, image sensor 14 may be able to deduce that a substance or object having a relatively high concentration of fluorescent material (or material tagged with fluorescent markers) is being imaged by image sensor 14. Image sensor 14 may also be able to determine the spatial distribution of a substance within a larger sample or object. For example, image sensor 14 may be sensitive to variances in concentration levels within a substance or object being imaged as a function of location (i.e., position) within that substance or object. If desired, image sensor 14 may be calibrated using a substance or object having a known concentration of fluorescent material. Image sensor 14 may also be able to track changes in concentrations and spatial distributions over time.

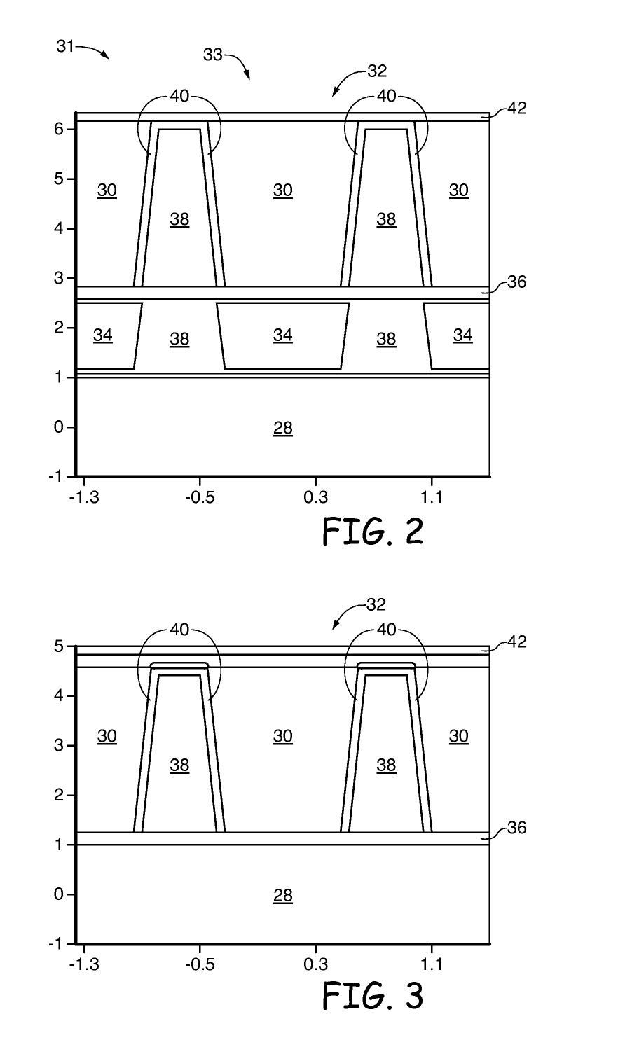

A side view of illustrative structures in image sensor 14 that may improve near field imaging performance is shown in FIG. 2. As shown in FIG. 2, image sensor 14 may include an array of image sensing pixels including photodiodes 28 with a stack of optical material above the photodiodes 28 of image sensor 14. The stack of optical material in FIG. 2 may form a light pipe 32. The light pipe 32 of FIG. 2 may sometimes be referred to herein as a dual light guide. As shown in FIG. 2, each light pipe 32 may be formed from structures (e.g., walls) such as dielectric 38 and cladding 40 that substantially surround a photodiode 28 (or multiple photodiodes 28). With at least some suitable arrangements, the walls of light pipe 32 may be shared between multiple light pipes (e.g., a given wall may form part of a light pipe for two adjacent photodiodes 28, a section of wall may form part of a light pipe for four adjacent photodiodes in corner areas at which the four photodiodes meet, etc.).

In the example of FIG. 2, the stack of optical material above photodiodes 28 may include an optical fill layer such as optical fill 34. With some suitable arrangements, optical fill material 34 may be a transparent dielectric material. If desired, optical fill material 34 may be selected to have an index of refraction that reduces reflections of incoming light and increases the amount of incoming (i.e., incident) light that reaches photodiodes 28.

Between each section of optical fill material 34, image sensor 14 may include dielectric material 38 (e.g., an oxide material). With some suitable arrangements, dielectric material 38 between each section of optical fill 34 may be clad (e.g., material 38 may be clad with a light blocking film such as aluminum or other metal or material to reduce unwanted light transmission). These types of arrangements may help to reduce transmission of light at relatively large angles of incidence (e.g., reducing the amount of light not coming from directly above a particular pixel that reaches that pixels), thereby improving the localization performance of image sensor 14 (e.g., the ability of image sensor 14 to accurately determine the location of near-field objects).

If desired, a passivation layer such as passivation layer 36 may be formed above optical fill layer 34. The passivation layer may be optically transparent. In general, passivation layer 36 may be formed from any suitable materials. As one example, passivation layer 36 may be formed from silicon nitride (Si₃N₄).

Above layers such as optional passivation layer 36, image sensor 14 may include materials such as color filter material 30, dielectric 38, and reflective material (as examples).

Color filter material 30 may serve to absorb unwanted frequencies of radiation. As examples, color filter material 30 may absorb wavelengths of radiation used in exciting fluorescent materials in objects being imaged while transmitting (i.e., passing) wavelengths of light emitted by those fluorescent materials (e.g., by the fluorescent properties of fluorescent materials being imaged). Color filter material 30 may, as an example, exponentially reduce the transmittance of an excitation wavelength or wavelengths (and other unwanted wavelengths) while allowing effective transmittance of fluorescent wavelengths (or the desired wavelengths) of objects under analysis (e.g., objects being imaged by image sensor 14 and within near field distances of image sensor 14).

As an example, color filter material 30 may suppress unwanted wavelengths such as an excitation wavelength by a factor of approximately 10⁻⁵ to 10⁻⁶ (e.g., color filter material 30 may reduce the intensity of unwanted wavelengths to approximately 10⁻⁵ to 10⁻⁶ of the initial intensity that strikes the color filter material 30). If desired color filter material 30 may be a low-pass or a band-pass filter (e.g. a filter that blocks relatively high frequency excitation wavelengths while transmitting relatively low frequency, when compared to excitation wavelengths, fluorescent wavelengths). As examples, color filter material 30 may have a wavelength cutoff of approximately 550 nanometers (e.g., color filter material 30 may block excitation light at wavelengths shorter than 550 nanometers while transmitting fluorescent light at wavelengths longer than 550 nanometers). With this type of arrangement, color filter material 30 may be suitable at least for imaging fluorescent material which is excited using laser light at wavelengths such as 488 nanometers or 532 nanometers and which fluoresces at longer wavelengths such as 580 to 600 nanometers.

Dielectric 38 may separate the vertical light pipes 32 for each photodiode 28 from the vertical light pipes 32 of neighboring photodiodes 28. With some suitable arrangements, reflective materials such as reflective layer stack 40 may be disposed on dielectric 38. Reflective layer stack 40 may, as an example, serve to ensure that any light that enters a given vertical light pipe 32 reaches the associated photodiode 28 at the bottom of that vertical light pipe 32 and does not cross-over into adjacent light pipes 32 (e.g., does not reach adjacent photodiodes 28). These types of arrangements may help to reduce optical cross-talk and increase localization capabilities (e.g., the ability of image sensor 14 to determine which pixels of image sensor 14 are below a particular object in the near-field regime of image sensor 14). As an example, reflective layer stack 40 may be formed from a reflective material such as aluminum, titanium, or titanium nitride. Reflective layer stack 40 may, as an example, have a thickness of approximately 500 Angstroms. With some suitable arrangements, reflective layer stack 40 may be formed together with (e.g., simultaneously and from the same material as) passivation layer 36. If desired, a dielectric overcoat may be formed on reflective layer stack 40 (e.g., a dielectric layer may be formed between reflective layer stack 40 and color filter material 30).

Reflective layer stack 40 may block stray and inclined radiation. In particular, reflective layer stack 40 may prevent radiation entering the light pipe 32 for a particular photodiode 28 from directions such as direction (e.g., inclined radiation) from reaching the photodiode 28. This type of configuration may help to increase the performance of image sensor 14 with respect to determining the position of objects being imaged (e.g., to determine which pixels imaged objects are above).

Reflective layer stack 40 may help to ensure that radiation from objects located above a particular photodiode 28, such as radiation entering light pipe 32 from direction 33, reach that particular photodiode 28. In particular, reflective layer stack 40 may help to reduce optical cross talk (e.g., reduce the chance that the radiation entering from direction 33 strikes another photodiode 28). Reflective layer stack 40 may reflect any light entering from direction 33 that would otherwise impinge on dielectric 38 and thereby funnel such light down light pipe 32 towards the appropriate photodiode 28.

If desired, image sensor 14 may include an overcoat layer 42. Overcoat layer 42 may, as an example, serve to protect vertical light pipes 32 from environmental contaminants, such as objects being imaged by image sensor 14 (e.g., objects within the near-field regime of image sensor 14, which may include objects on the surface of overcoat layer 42). Layer 42 may act as a passivation layer that protects layers below layer 42 from corrosive chemicals used in analysis (e.g., chemicals used in imaging objects at near field ranges). With some suitable arrangements, overcoat layer 42 may be formed from an optically transparent oxide material (e.g., a material optically transparent at least at wavelengths at which objects being imaged emit or reflect light).

As shown in FIG. 3, image sensor 14 may include a stack of optical material above photodiodes 28 that does not include optical fill material 34. With arrangements of this type, color filter material 30 may extend closer to photodiodes 28 or may even be adjacent to photodiodes 28. If desired, a passivation layer such as passivation layer 36 may separate color filter material 30 and photodiodes 28 as shown in the example of FIG. 3. The light pipe 32 of FIG. 3 may sometimes be referred to herein as a single light guide. In at least some embodiments, the single light guide arrangement of FIG. 3 may have greater performance than the dual light guide arrangement of FIG. 2 (e.g., the single light guide arrangement of FIG. 3 may be more optimized for specific applications including near field imaging applications).

The structures shown in FIGS. 2 and 3 may not be to scale. The x-axis and y-axis scale markings of the diagrams of FIGS. 2 and 3 may, as an example, be in micrometers. With such an arrangement, the color filter material 30 of FIGS. 2 and 3 may have a thickness of approximately 3.5 micrometers. In general, color filter material 30 may have any suitable thickness. Examples of suitable thicknesses of color filter material 30 include, but are not limited to, less than 1 micrometer, approximately 1 micrometer, approximately 1.5 micrometers, approximately 2 micrometers, approximately 2.5 micrometers, approximately 3 micrometers, approximately 3.5 micrometers, approximately 4 micrometers, approximately 4.5 micrometers, approximately 5 micrometers, and more than approximately 5 micrometers.

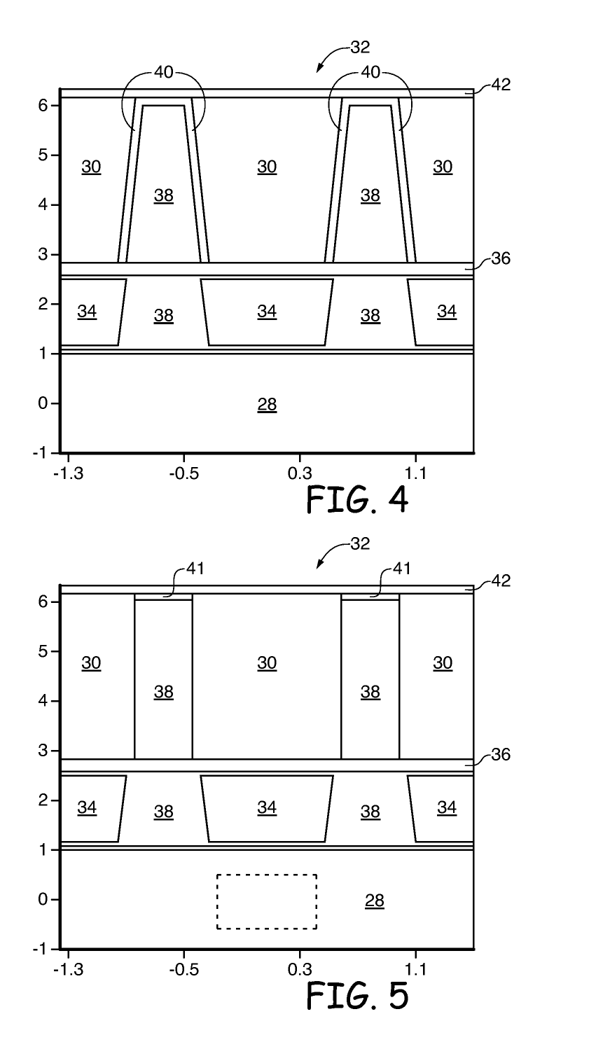

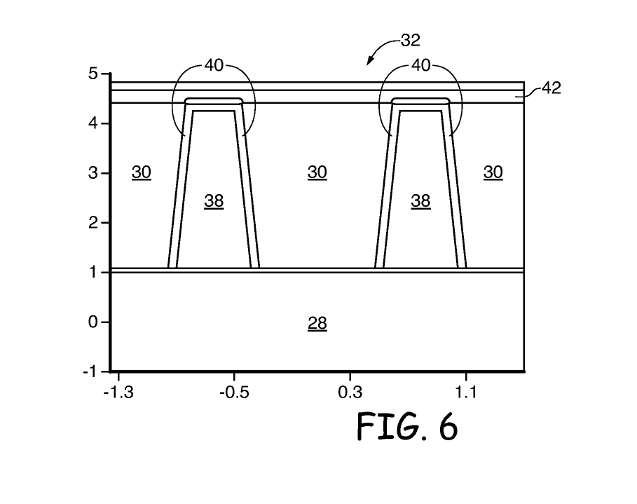

FIGS. 4, 5, and 6 illustrate examples of various structures that may form vertical light pipes 32 for photodiodes 28. Possible variations on the structures that form vertical light pipes 32 include, but are not limited to, a single stage structure (as illustrated in FIGS. 3 and 6), a dual stage structure (as illustrated in FIGS. 2, 4, and 5), a clad light guide structure in which a cladding layer such as layer 40 is included (as illustrated in FIGS. 2, 3, 4, and 6), a tapered light guide structure in which the walls of light pipe 32 are tapered at a positive or negative angle (as illustrated in FIGS. 2, 3, 4, and 6), a flat light guide structure in which the walls of light pipe 32 have approximately no taper (e.g., are approximately vertical) (as illustrated in FIG. 5), a light guide structure having a light blocking structure such as light block 41, which may only be formed on the tops of dielectric 38 (as illustrated in FIG. 5), a sealed light guide structure in which a cladding layer such as layer 40 encloses dielectric material 38 (as illustrated in FIGS. 2, 3, 4, and 6), etc.

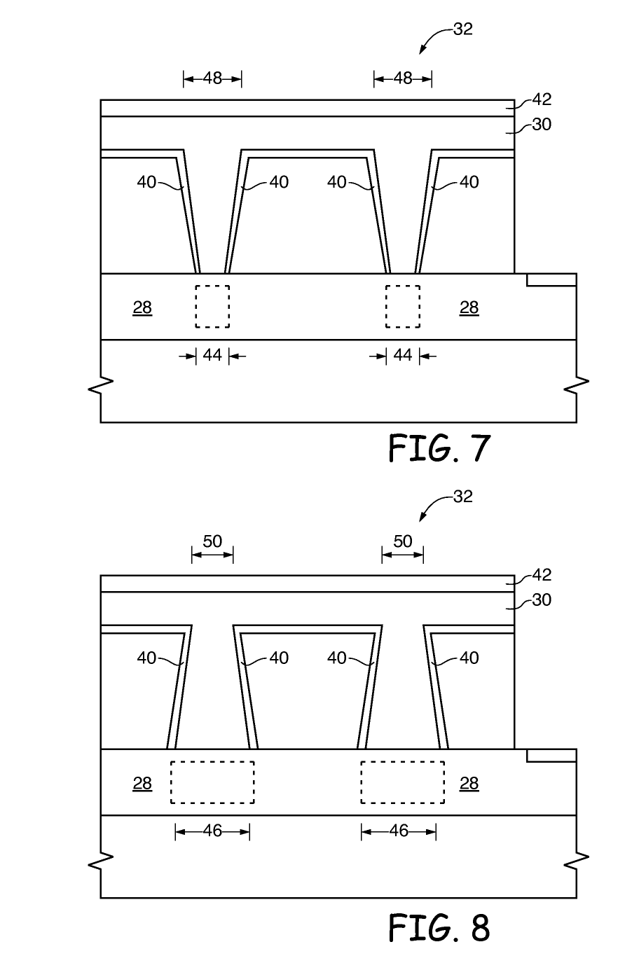

As shown in FIGS. 7 and 8, the angles of walls that form vertical light pipes 32 may be varied at adjust the imaging characteristics of image sensor 14. FIG. 7 illustrates a prograde arrangement in which the opening formed by the walls of vertical light pipes 32 is at its smallest size adjacent to photodiodes 28 and increases in size with increasing distance from photodiodes 28. FIG. 8 illustrates a retrograde arrangement in which the opening formed by the walls of vertical light pipes 32 is at its largest size adjacent to photodiodes 28 and decreases in size with increasing distance from photodiodes 28.

Retrograde arrangements such as the example of FIG. 8 may be advantageous when it is desired to have each photodiode 28 collect photons over a relatively wide range 50 of angles of incidence. In particular, due to the potentially greater size 46 (e.g., width and length) of photodiodes 28 in retrograde arrangements (e.g., photodiodes 28 may be larger in retrograde arrangements as the openings of light guides 32 at the bottom of the light guides 32 may be relatively large in retrograde arrangements), photodiodes 28 in retrograde arrangements may receive incident light that originates (from objects such as fluorescent objects) from anywhere within the illustrative range 50 of angles of incidence shown in FIG. 8. As examples, the range 50 of angles of incidence shown in FIG. 8 may be less than approximately 10 degrees, approximately 10 degrees, approximately 20 degrees, approximately 30 degrees, approximately 40 degrees, approximately 45 degrees, approximately 50 degrees, approximately 60 degrees, or more than approximately 60 degrees.

Prograde arrangements such as the example of FIG. 7 may be advantageous when it is desired to restrict the range of angles of incidence over which photons are collected by photosensor 28. Such configurations may serve to increase the localization performance of image sensor 14 (e.g., the ability of image sensor 14 to accurately determine the location of an object over image sensor 14, by determining which pixel(s) the object is located over). In particular, due to the potentially smaller size 44 (e.g., width and length) of photodiodes 28 in prograde arrangements (e.g., photodiodes 28 may be smaller in prograde arrangements as the openings of light guides 32 at the bottom of the light guides 32 may be relatively small in prograde arrangements), photodiodes 28 in prograde arrangements may receive incident light that originates (from objects such as fluorescent objects) from anywhere within the illustrative range 48 of angles of incidence shown in FIG. 7. As examples, the range 48 of angles of incidence shown in FIG. 7 may be less than approximately 10 degrees, approximately 10 degrees, approximately 20 degrees, approximately 30 degrees, approximately 40 degrees, approximately 45 degrees, approximately 50 degrees, approximately 60 degrees, or more than approximately 60 degrees.

In general, the range 48 of angles of incidence over which photodiodes 28 are sensitive to incident light (in prograde arrangements) may be smaller than the range 50 of angles of incidence over which photodiodes 28 are sensitive to incident light (in retrograde arrangements). Similarly, the localization performance of image sensor 14 may be greater in prograde arrangements that in retrograde arrangements. In at least some arrangements, vertical light guides 48 may have walls that are relatively vertical (e.g., neither retrograde nor prograde) and, in these arrangements, image sensor 14 may have characteristics between those of retrograde and prograde arrangements. The walls of light pipes 32 may be formed using any desired combination of Bosch and non-Bosch processes.

As an example, the walls of vertical light guide 32 may have a slope approximately 2 degrees from vertical in retrograde and prograde embodiments. In general, the walls of vertical light guide may have any desired slope.

If desired, the same type of color filter material 30 may cover each photodiode 28 of image sensor 14. With this type of arrangement, each photodiode 28 may be sensitive to the same wavelengths, thereby providing maximum resolution to those wavelengths.

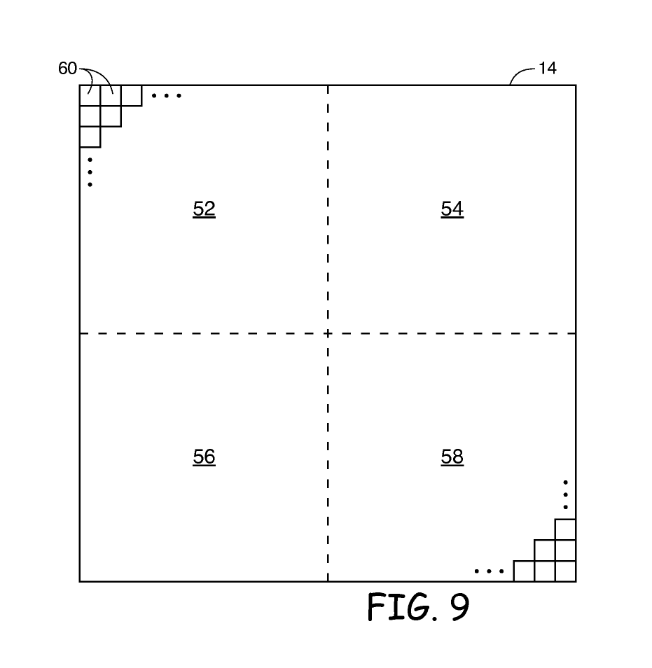

With other suitable arrangements, different types of color filter 30 may be patterned over different pixels 60 within image sensor 14. With arrangements of this type, image sensor 14 may have two, three, four, or more groups of pixels 60, where each group of pixels 60 (e.g., photodiodes 28) is sensitive to a respective wavelength or set of wavelengths (e.g., a first group of pixels 60 may be sensitive to a first fluorescent wavelength, a second group of pixels 60 may be sensitive to a second fluorescent wavelength, etc.). Each group of pixels 60 may be formed together so that the pixels 60 of a particular group are only adjacent (except along the edges of that group) to other photodiodes of that group. An arrangement of this type is shown in FIG. 9.

As shown in FIG. 9, image sensor 14 may be partitioned into sections such as sections 52, 54, 56, and 58, each of which corresponds to a particular group of pixels 60 that is sensitive to a particular wavelength or set of wavelengths of radiation (e.g., each of which has color filter material 30 that transmits a particular wavelength or set of wavelengths of radiation to the photodiodes 28 of that group). As an example, sections 52, 54, 56, and 58 may include one or more sections (in any desired combination) sensitive to red light, blue light, green light, ultraviolet light, infrared light, or specific fluorescent wavelengths (e.g., specific wavelengths emitted by fluorescent materials or markers). As another example, each of sections 52, 54, 56, and 58 may be sensitive to a subset of wavelengths from within a larger range of wavelengths (e.g., each of sections 52, 54, 56, and 58 may be sensitive to a first range of red wavelengths, a second range of red wavelengths, etc.). These types of arrangements may allow imager 14 to maintain full resolution for different types of wavelengths, although imager 14 may only be sensitive to certain wavelengths over a particular section of imager 14.

With at least some other arrangements, the pixels 60 of each group of photodiodes (e.g., the photodiodes sensitive to particular wavelengths) may be intermingled with the pixels 60 of one or more other groups of photodiodes. In arrangements of this type, a repeating block of pixels 60 may be used in forming image sensor 14. The repeating block may include multiple different pixels 60 each of which is sensitive to a particular wavelength or set of wavelengths of radiation. While these types of arrangements may reduce the resolution of imager 14 with respect to a particular wavelength, imager 14 may be sensitive to a wider range of wavelengths over a larger portion of the area of imager 14 (relative to arrangements such as those described in connection with FIG. 9).

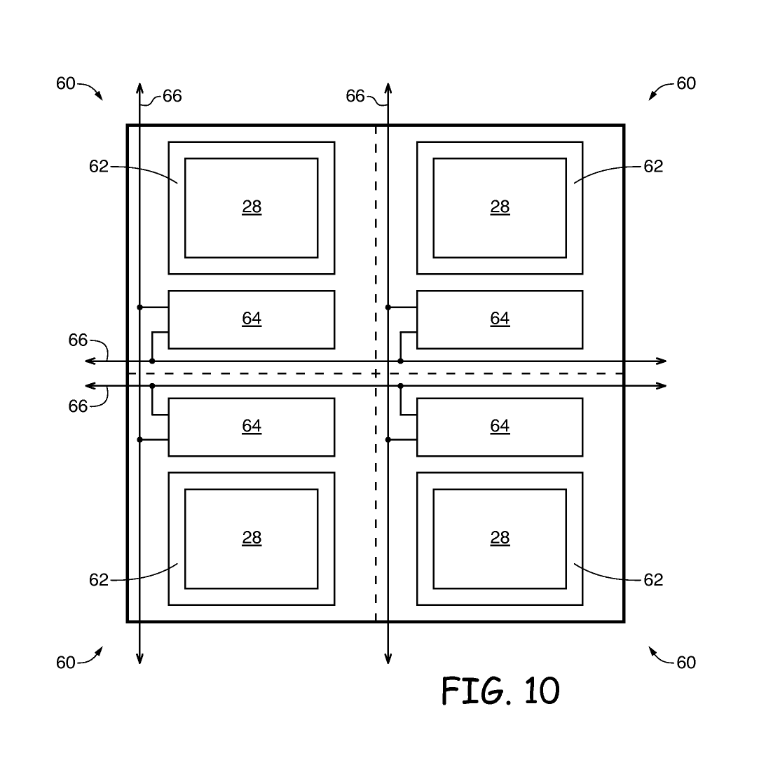

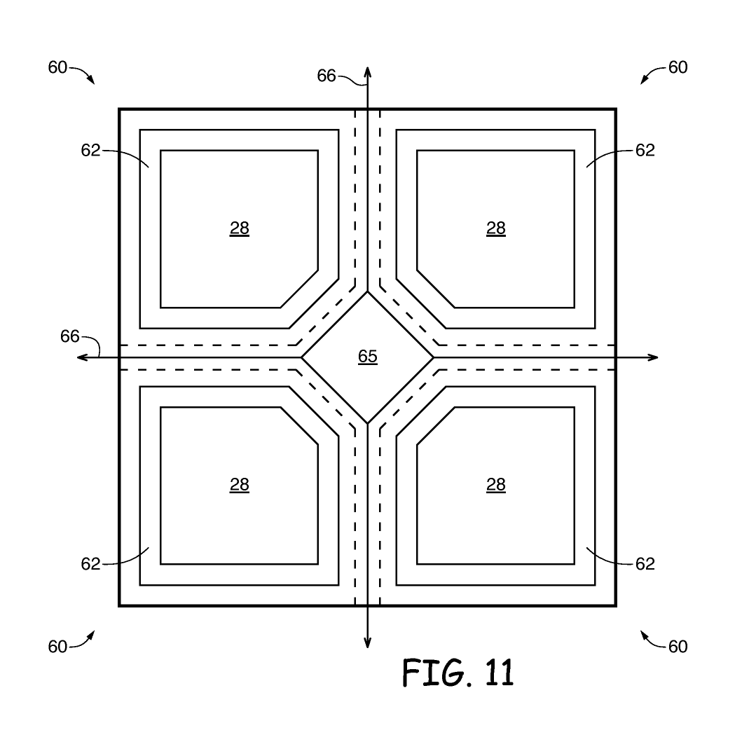

A top view of a group of four illustrative pixels 60 that may be used in forming an array of pixels in image sensor 14 is shown in FIG. 10. As shown in FIG. 10, pixel components such as transfer transistors, source-follower transistors, reset transistors, address transistors, floating diffusion nodes, etc. may be located in regions 64. In some embodiments, pixel components may be shared by multiple pixels and arranging regions 64 such that the regions 64 associated with two or more pixels are adjoining may facilitate the sharing of pixel components between those pixels. The pixel components in regions 64 may be connected to image readout circuitry, address circuitry, bias circuitry, and other components in image sensor 14 by conductive lines 66 (e.g., interconnects 66).

As shown in FIG. 10, photodiodes 28 may have a rectangular shape and the walls 62 of light pipes 32 may have a rectangular shape. This is merely illustrative. In general, photodiodes 28 and the walls 62 of light pipes 32 may have any desired shapes such as circular shapes, oval shapes, triangular shapes, polygonal shapes, etc. In at least some embodiments, photodiodes 28 and the walls 62 of light pipes 32 may be provided in non-symmetrical shapes. Such arrangements may facilitate reducing the area consumed by each pixel 60 in image sensor 14 (e.g., in reducing the size of image sensor 14 while maintaining a particular resolution or number of pixels 60).

An illustrative example in which pixels 60 are arranged such that circuitry 64 of FIG. 10 may be shared by multiple pixels 60 is shown in FIG. 11. As shown in FIG. 11, the circuitry 64 associated with four pixels 60 may be grouped together as circuitry 65. Circuitry 65 may, in some arrangements, include all of the circuits associated with circuitry 64 of four separate pixels 60. In other arrangements, circuitry may be shared by the four pixels 60 (e.g., a common source-follower transistor may be shared by all four pixels 60, a common floating diffusion node may be shared by all four pixels 60, a common reset transistor may be shared by all four pixels 60, etc.). These types of arrangements may be used in reducing the amount of circuitry in sensor 14 and/or in configuring pixels 60 to implement charge summing (e.g., arrangements in which pixels 60 combine their accumulated charges onto a single floating diffusion node to increase signal-to-noise ratios in situations such as low light and high speed situations).

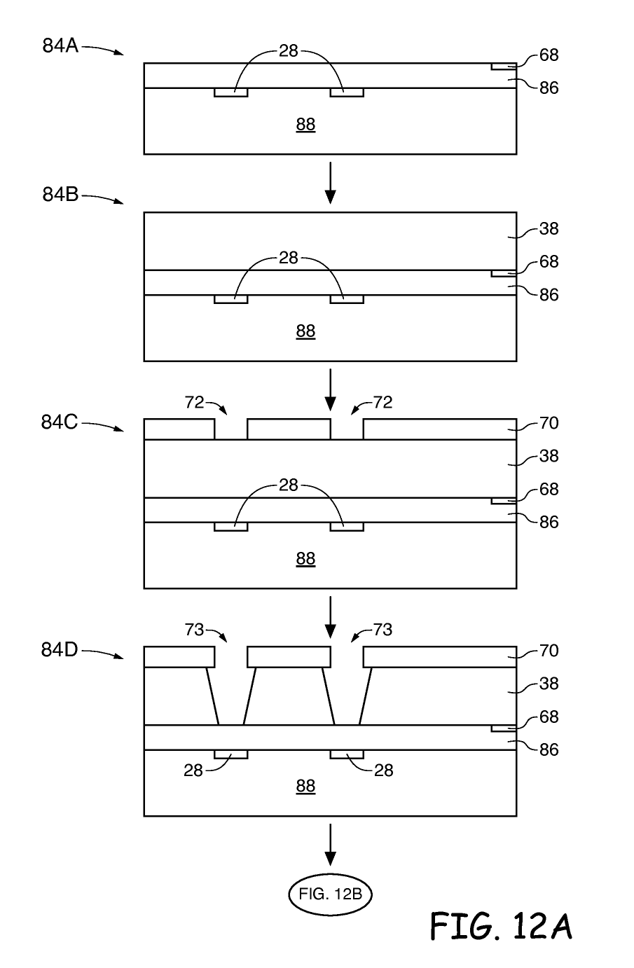

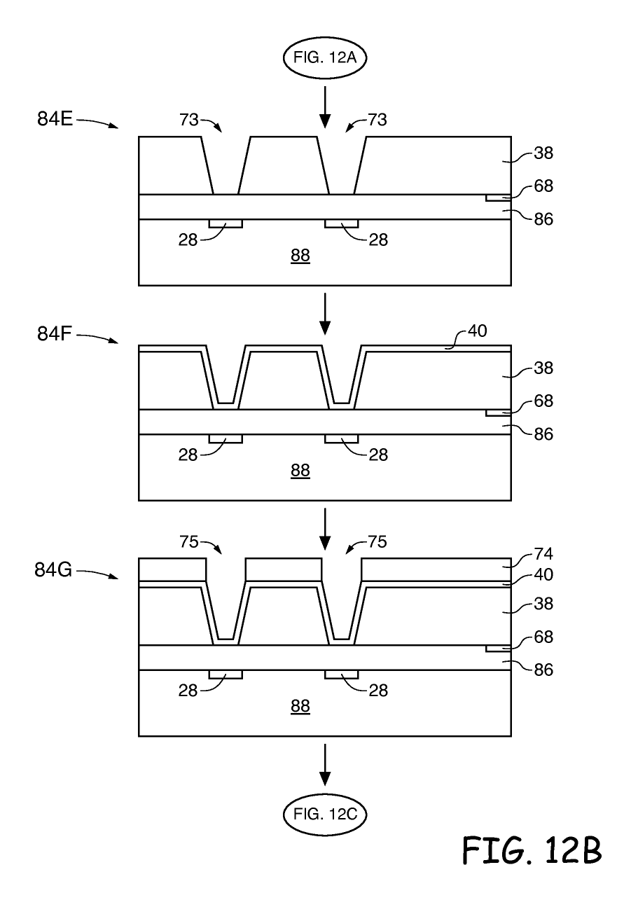

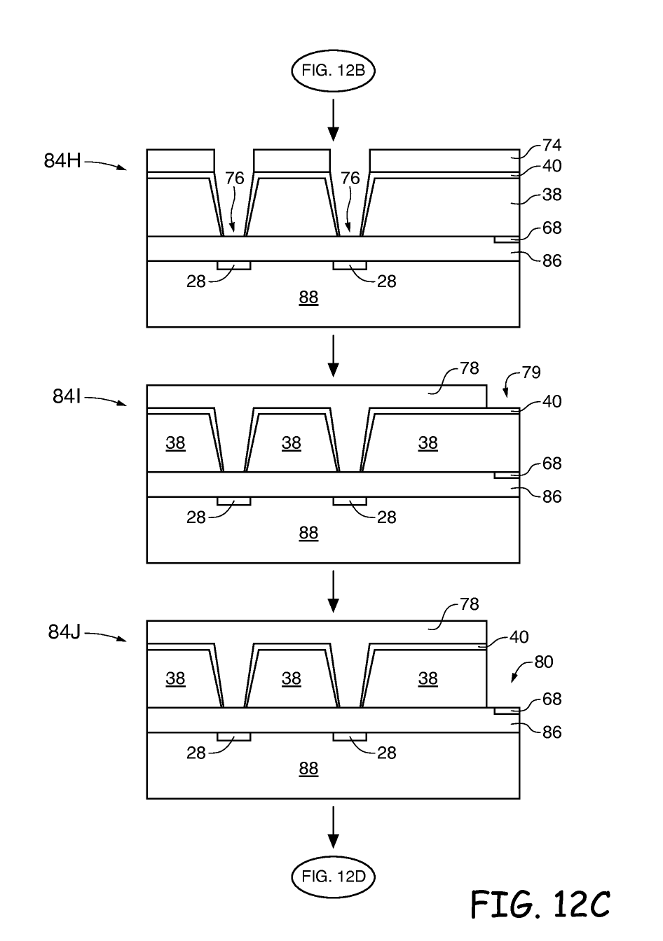

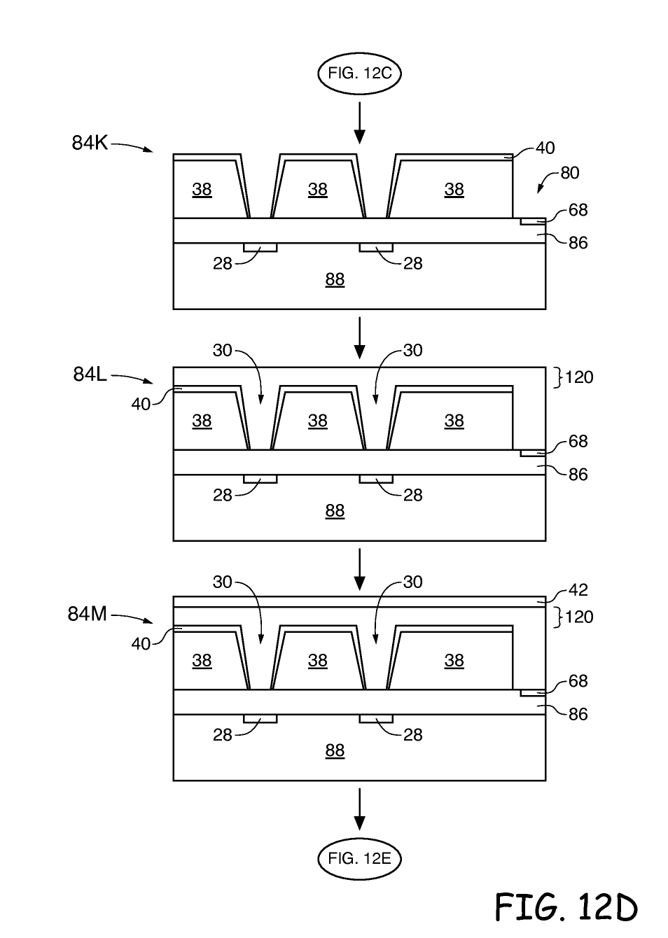

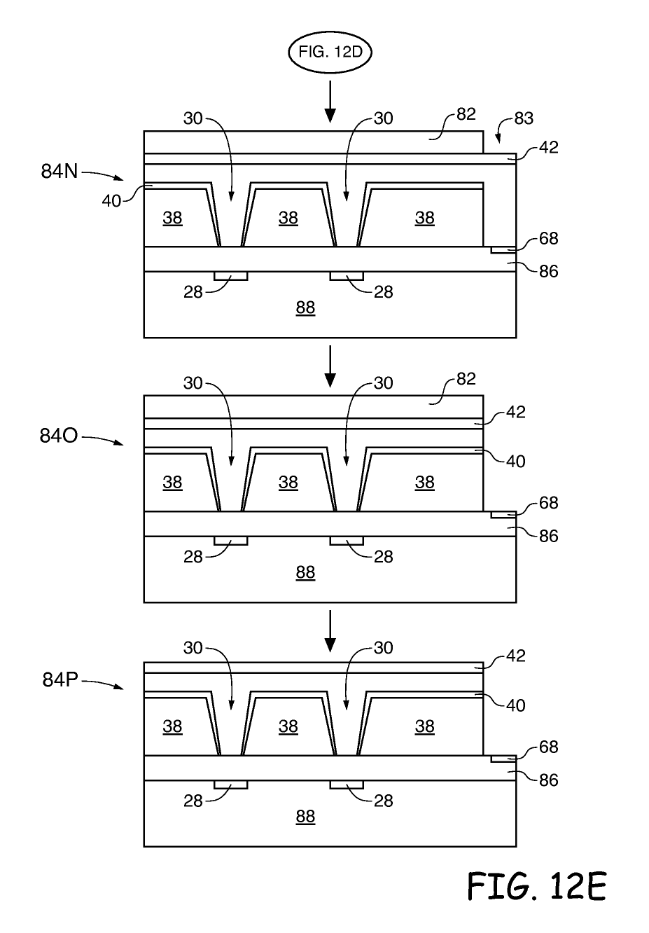

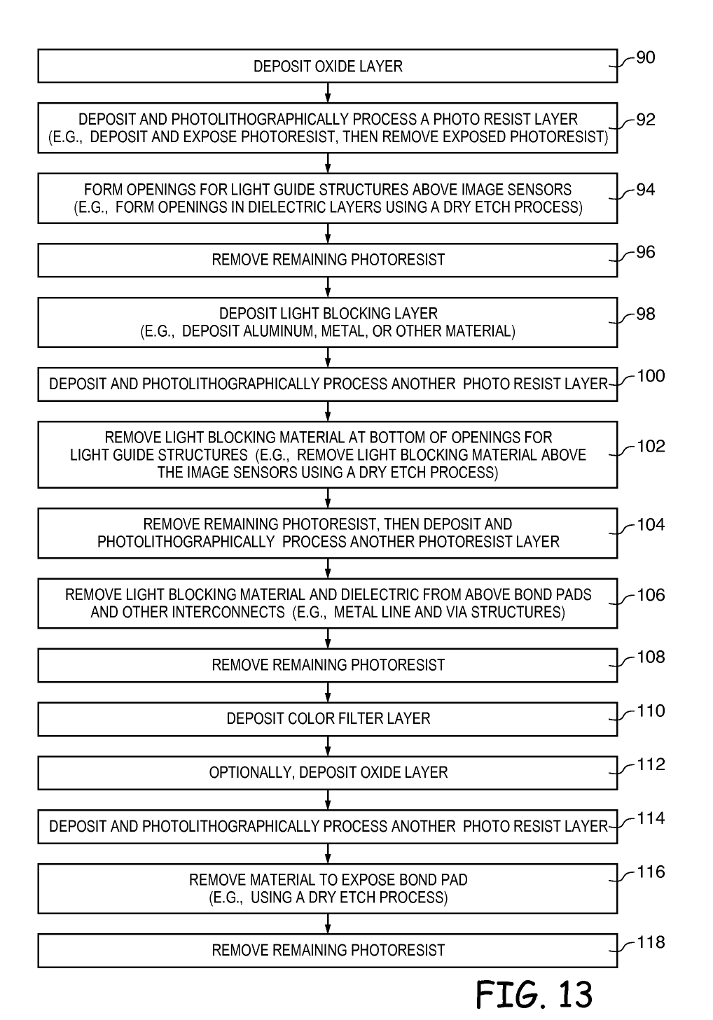

Illustrative processes that may be involved in forming an image sensor 14 with light guide structures configured for near field imaging such as light pipe 32 of FIG. 3 are shown in the process flow cross-sectional side views of FIG. 12. Steps corresponding to the process flow cross-sectional side views of FIG. 12 are shown in FIG. 13.

As shown in cross-sectional view 84A, an imager wafer having a substrate layer 88 that may include components such as photodiodes 28. The imager wafer may, as an example, include a layer such as nitride passivation layer 86 that covers substrate layer 88. Components such as bond pad 68 may be provided may be provided on passivation layer 86. Substrate layer 88 may, if desired, be coupled to a carrier (e.g., a temporary or a permanent carrier). In the example of FIG. 12, photodiodes 28 are shown as being on the frontside of substrate 88. If desired, photodiodes 28 may be formed on the backside of substrate 88.

In step 90 and as shown in cross-sectional view 84B, material such as an oxide material 38 (FIG. 3) may be deposited on the imager wafer (e.g., as part of forming dielectric layer 38 of FIG. 3). The material deposited in cross-sectional view 84B may be deposited using any desired process such as a chemical vapor deposition process.

In step 92 and as shown in cross-sectional view 84C, a layer of photoresist 70 may be deposited and processed (e.g., deposited, photolithographically exposed, and developed to remove the exposed, or unexposed if using negative photoresist, photoresist portions). The processed photoresist 70 may include openings 72. Lithographic processes may be used to pattern quadrilateral openings 72, circular openings 72, or openings 72 having other shapes. Openings 72 may be formed over each pixel 60 (e.g., each photodiode 28), over every other pixel (in a checkerboard pattern), or in other combinations.

In step 94 and as shown in cross-sectional view 84D, an etching process may be used to create openings 73 that extend through oxide 38 (e.g., to form the openings for light pipes 32). With one suitable arrangement, a dry etch process may be used to form openings 73 for light pipes 32. As an example, the etching process may form openings 73 having a truncated cylindrical shape, a pyramid shape, an inverted truncated cone shape, or any other desired shape. The shape of openings 73 may depend on the shape of openings 72 in photoresist 70 and may depend on the particular etching process used in forming openings 73 (e.g., the length of the etching process). As an example, openings 73 may have a slope of approximately 2 degrees from vertical.

In step 96 and as shown in cross-sectional view 84E, any remaining photoresist 70 may be removed (i.e., stripped). If desired, the surface of dielectric 38 may be cleaned after the remaining photoresist 70 is removed (e.g., to promote better adhesion of dielectric 38 to subsequent layers).

In step 98 and as shown in cross-sectional view 84F, a light blocking layer such as reflective cladding layer 40 may be deposited on dielectric 38. As an example, reflective layer 40 may be aluminum, another metal, or a material film stack and may be deposited using a physical vapor deposition processes. The layer 40 may provide blocking of stray or inclined radiation. While layer 40 may be referred to herein as a reflective layer, in general layer 40 need not be reflective. Layer 40 may have a thickness sufficient to block transmission of light through layer 40. As an example, layer 40 may have a thickness of approximately 500 angstroms.

In step 100 and as shown in cross-sectional view 84G, a layer of photoresist 74 may be deposited and processed. The processed photoresist 74 may include openings 75.

In step 102 and as shown in cross-sectional view 84H, an etching process may be used to clear light blocking material 40 from the bottom 76 of the vertical light guides 32 (e.g., from above photodiodes 28).

In step 104 and as shown in cross-sectional view 84I, the remaining photoresist from the layer of photoresist 74 may be removed (and reflective layer 40 and passivation layer 86 cleaned) and a layer of photoresist 78 may be deposited and processed. The processed photoresist 78 may include openings 79.

In step 106 and as shown in cross-sectional view 84J, an etching process may be used to clear light blocking material 40 and dielectric 38 from above bond pads 68 and from above other interconnects (e.g., interconnects between components such as bond pad 68 and photodiodes 28).

If desired, the dual set of etch processes of steps 100, 102, 104, and 106 may be replaced with single set of etch processes. For example, a single layer of photoresist may be deposited and patterned with both openings 76 and 79 and single etching process may clear light guide 32, interconnects, and bond pads 68. These types of arrangements may require adequate etch controls (e.g., to ensure that bond pad 68 is not etched away beyond acceptable parameters and to ensure that passivation layer 86 is not etched into beyond acceptable parameters).

With other suitable arrangements, the etching of the opening above bond pads 68 in steps 104 and 106 may be omitted. With arrangements of this type, the subsequent etching (in steps 114, 116, and 118) of the opening above bond pads 68 may involve etching through reflective layer 40 and dielectric material 38 in addition to the color filter material 30.

In step 108 and as shown in cross-sectional view 84K, any remaining photoresist 78 may be removed (i.e., stripped). If desired, the surfaces of reflective layer 40, passivation layer 86, and bond pads 68 may be cleaned after the remaining photoresist 78 is removed (e.g., to promote better adhesion to subsequent layers).

In step 110 and as shown in cross-sectional view 84L, a color filter material such as color filter material 30 of FIG. 3 may be deposited. Color filter material 30 may be deposited using a spin coating process to fill light guides 32 and, if desired, to form an additional layer 120 of color filter material 30 above the light pipes (e.g., above the top of reflective layer 40). Color filter material 30 may be deposited in multiple layers or in a single layer. Color filter material 30 may be photo-definable. In arrangements in which different forms of color filter material 30 are used in image sensor 14 (e.g., to provide pixels 60 sensitive to different wavelengths of radiation), step 100 may include additional steps of depositing photoresist, forming openings for a given type of pixel (e.g., for pixels sensitive to a particular set of wavelengths), depositing color filter material 30 for that type of pixel (e.g., depositing color filter material that transmits the desired set of wavelengths), removing remaining photoresist, and repeating these step for each different type of pixel.

In optional step 112 and as shown in cross-sectional view 84M, layer 42 may be deposited. Layer 42 may be, as examples, a protective surface layer, a dielectric layer, and a passivation layer (e.g., a layer that passivates color filter material 30). Layer 42 may be formed using, as an example, chemical vapor deposition processes.

In step 114 and as shown in cross-sectional view 84N, a layer of photoresist 82 may be deposited and processed. The processed photoresist 82 may include openings 83.

In step 116 and as shown in cross-sectional view 84O, an etching process may be used to clear color filter material 30 and overcoat layer 42 from above bond pads 68 and from above other interconnects (e.g., interconnects between components such as bond pad 68 and photodiodes 28).

In step 118 and as shown in cross-sectional view 84P, the remaining photoresist from the layer of photoresist 82 may be removed (and bond pads 68 and interconnects cleaned).

Various embodiments have been described illustrating imagers with structures for near field imaging.

An imaging system may include an image sensor configured to image materials at near field imaging ranges from the image sensor.

Near field imaging ranges may be on the scale of 1-10 pixel sizes from image sensor 14. The materials being imaged may be fluorescent materials that emit radiation at fluorescent wavelengths when the materials are exposed to radiation at excitation wavelengths.

The image sensor may include light guides that reduce cross-talk between pixels and improve localization of emitted radiation, thereby allowing the image sensor to determine which pixel(s) is (are) located beneath the materials being imaged. The light guides may include may include sloped sidewalls and may include reflective sidewalls, which may improve radiation collection (e.g., efficiency) and localization of emitted radiation.

The light guides may be formed from a dual light guide structure in which a first layer includes a transparent optical fill layer and a second layer includes color filter material. Alternatively, the light guides may be formed from a single light guide structure in which a single layer of color filter material fills the light guide structure.

The light guides may include light reflective material only along the tops of sidewalls. If desired, the light guides may include light reflective material along the sides of the sidewalls. The reflective material may seal off the material that forms the sidewalls (e.g., separate the material that forms the sidewalls from dielectric, color filter material, and other materials).

The sidewalls of the light guides may have any desired shape. As examples, the light guides may have vertical sidewalls or sloped (e.g., retrograde or prograde) sidewalls.

The image sensor may include color filter materials that block radiation at excitation wavelengths while transmitting radiation at fluorescent wavelengths. The color filter materials may, as an example, be formed within the light guides. If desired, the color filter materials may extend vertically above the light guides (e.g., to increase the amount of color filter material that incident light passes through).

The foregoing is merely illustrative of the principles of this invention which can be practiced in other embodiments.

What is claimed is:

1. An image sensor sensitive to radiation emitted from a source located in a near-field region of the image sensor, wherein the source emits radiation at a fluorescent wavelength when the source is exposed to radiation at an excitation wavelength, the image sensor comprising:
a plurality of image sensing pixels; and
a layer of color filter material that absorbs radiation at the excitation wavelength and transmits radiation at the fluorescent wavelength to the plurality of image sensing pixels.

2. The image sensor defined in claim 1 wherein the image sensor does not include any macro-lenses that focus radiation onto all of the image sensing pixels.

3. The image sensor defined in claim 1 further comprising:
a plurality of microlenses, each of which focuses radiation on a respective one of the image sensing pixels.

4. The image sensor defined in claim 1 further comprising:
a plurality of light guide sidewalls that surround light pipes over each of the image sensing pixels.

5. The image sensor defined in claim 4 wherein the color filter material is disposed between the plurality of light guide sidewalls.

6. The image sensor defined in claim 5 wherein the color filter material extends above the plurality of light guide sidewalls.

7. The image sensor defined in claim 4 wherein image sensing pixels lie in a first plane and wherein the light guide sidewalls are disposed perpendicular to the first plane.

8. The image sensor defined in claim 4 wherein the light pipes comprise a plurality of tapered light pipes, each of which is associated with and located above a respective one of the image sensing pixels, wherein each tapered light pipe of the plurality of tapered light pipes has a size that increases with increasing distance from the image sensing pixel associated with that tapered light pipe.

9. The image sensor defined in claim 4 herein the light pipes comprise a plurality of tapered light pipes, each of which is associated with and located above a respective one of the image sensing pixels, wherein each tapered light pipe of the plurality of tapered light pipes has a size that decreases with increasing distance from the image sensing pixel associated with that tapered light pipe.

10. The image sensor defined in claim 4 further comprising reflective material covering the plurality of light guide sidewalls.

11. The image sensor defined in claim 4 further comprising a material covering the plurality of light guide sidewalls, wherein the material comprises a metal selected from the group consisting of: aluminum, titanium, and titanium nitride.

12. The image sensor defined in claim 1 further comprising:
an oxide layer above the layer of color filter material, wherein each of the image sensing pixels has a common pixel size and wherein the near-field region includes distances from the image sensor of less than the common pixel size.

13. The image sensor defined in claim 1 further comprising:
an oxide layer above the layer of color filter material, wherein each of the image sensing pixels has a common pixel size and wherein the near-field region includes distances from the image sensor of less than ten times the common pixel size.

14. The image sensor defined in claim 1 wherein the layer of color filter material reduces the intensity of the radiation at the excitation wavelength from an initial intensity at which the radiation at the excitation wavelength strikes the color filter material to a reduced intensity of at most 10⁻⁵ times the initial intensity.

15. The image sensor defined in claim 1 further comprising a transparent optical fill layer between the plurality of image sensing pixels and the layer of color filter material.

16. The image sensor defined in claim 15 further comprising a passivation layer between the transparent optical fill layer and the layer of color filter material.

17. The image sensor defined in claim 16 further comprising:
a plurality of light guide sidewalls that surround light pipes over each of the image sensing pixels, wherein the passivation layer passes through the light guide sidewalls.

18. An image sensor sensitive to radiation emitted from sources located in a near-field region of the image sensor, wherein the sources emit radiation at a first fluorescent wavelength when exposed to radiation at a first excitation wavelength, wherein the sources emit radiation at a second fluorescent wavelength when exposed to radiation at a second excitation wavelength, the image sensor comprising:
first and second pluralities of image sensing pixels;
a first layer of color filter material that is disposed above the image sensing pixels in the first plurality of image sensing pixels, absorbs radiation at the first excitation wavelength, and transmits radiation at the first fluorescent wavelength to the image sensing pixels in the first plurality of image sensing pixels; and
a second layer of color filter material that is disposed above the image sensing pixels in the second plurality of image sensing pixels, absorbs radiation at the second excitation wavelength, and transmits radiation at the second fluorescent wavelength to the image sensing pixels in the second plurality of image sensing pixels.

19. The image sensor defined in claim 18 further comprising:
an oxide layer above the first and second layers of color filter material, wherein each of the image sensing pixels of the first and second pluralities of image sensing pixels has a common pixel size and wherein the near-field region includes distances from the image sensor of less than the common pixel size.

20. The image sensor defined in claim 18 further comprising:
an oxide layer above the first and second layers of color filter material, wherein each of the image sensing pixels of the first and second plurality of image sensing pixels has a common pixel size and wherein the near-field region includes distances from the image sensor of less than ten times the common pixel size.
